(19) United States
(12) Patent Application Publication
(10) Pub. No.: US 2017/0030962 A1
(43) Pub. Date: Feb. 2, 2017

(54) CIRCUIT FOR DETECTING FAILURE OF INSULATED GATE BIPOLAR TRANSISTOR (IGBT) POWER MODULE

(71) Applicants: Hyundai Motor Company, Seoul (KR); Kia Motors Corporation, Seoul (KR)

(72) Inventors: Ji Woong Jang, Hwaseong (KR); Ki Jong Lee, Osan (KR); Kang Ho Jeong, Changwon (KR)

(21) Appl. No.: 14/960,362

(22) Filed: Dec. 5, 2015

(30) Foreign Application Priority Data
Jul. 27, 2015 (KR) 10-2015-0105826

(51) Int. Cl. G01R 31/26; H01L 25/16; H01L 29/739

(52) U.S. Cl. CPC G01R 31/2608; H01L 29/7397; H01L 25/167

(57) ABSTRACT

A circuit for detecting failure of an insulated-gate bipolar transistor (IGBT) power module, is provided to combine failure detecting signals of an IGBT power module using a photo coupler to transmit the isolated signals. The failure detecting circuit includes a circuit that combines six phase isolated failure detecting signals transmitted from a gate drive IC via a photo coupler to be one signal. A plurality of logic gate ICs are omitted, to reduce a material cost, a size of a circuit board, and power consumption.

### CROSS-REFERENCE TO RELATED APPLICATION

This application claims under 35 U.S.C. §119(a) the benefit of Korean Patent Application No. 10-2015-0105826 filed on Jul. 27, 2015, the entire contents of which are incorporated herein by reference.

### BACKGROUND

(a) Technical Field

The present disclosure relates to a circuit for detecting failure of an insulated-gate bipolar transistor (IGBT) power module and more particularly, it relates to a circuit for detecting failure of an IGBT power module which combines to combine failure detecting signals of an IGBT power module that use a photo coupler to transmit the isolated signals.

(b) Background Art

Generally, a circuit board which is included in a control system of an eco-friendly vehicle such as an electric vehicle or a hybrid vehicle is divided into a high voltage region in which a motor is driven using a high voltage battery and a low voltage region in which a driving signal of a microcomputer is transmitted or a sensing signal of a sensor is processed. For example, the circuit board includes an inverter that operates a three-phase motor having a U phase, a V phase, and a W phase mounted in the control system of the eco-friendly vehicle. The inverter includes an IGBT power module which applies a three phase current to a motor using a pulse-width modulation (PWM) control based on a current command and a failure detecting circuit for the IGBT power module. Since each of the three phases (U phase, V phase, and W phase) includes a top phase and a bottom phase, the IGBT power module is configured by total of six phase (UT phase, UB phase, VT phase, VB phase, WT phase, and WB phase) IGBTs, and the failure detecting circuit is connected to each phase IGBT via an isolation type photo coupler.

The above information disclosed in this section is merely for enhancement of understanding of the background of the invention and therefore it may contain information that does not form the prior art that is already known in this country to a person of ordinary skill in the art.

### SUMMARY

The present invention provides a failure detecting circuit of an IGBT power module that builds a circuit that combines an isolated six phase failure detecting signals that are transmitted from a gate drive integrated circuit (IC) via a photo coupler to be one signal, without using a plurality of logic gate ICs. The material cost, a size of a circuit board, and power consumption may be reduced.

In one aspect, an exemplary embodiment a failure detecting circuit for an IGBT power module may include a gate drive IC configured to operate a plurality of IGBT gates of an IGBT power module and a plurality of photo couplers configured to transmit an isolated digital failure detecting signal detected by the gate drive IC to a low voltage region. For example, one integrated signal line may be coupled to an output terminal of the photo couplers to couple the photo couplers in series. A digital power line that supplies power may be coupled to the integrated signal line to determine the failure of the IGBT power module based on a voltage signal that may be transmitted from the integrated signal line and the digital power line.

In an exemplary embodiment, a first end of the integrated signal line may be grounded and an inverter gate that may be configured to output a signal that indicates whether the IGBT power module is in a failure state may be coupled to the other end of the integrated signal line. A resistor may have a resistance set in consideration of voltage levels of a high level input (V_IH) and a low level input (V_IL) of the inverter gate may be coupled to the digital power line. Through the aforementioned technical solutions, the present invention provides the effects below.

A plurality of photo coupler output terminals may be coupled in series by one combined signal line to combine isolated six phase failure detecting signals that may be configured to be transmitted from the gate drive IC via the photo coupler into one signal.

Accordingly the material cost, a size of the board, and power consumption may be reduced without providing the plurality of logic gate ICs of the related art.

### BRIEF DESCRIPTION OF THE DRAWINGS

The above and other features of the present invention will now be described in detail with reference to exemplary embodiments thereof illustrated in the accompanying drawings:

FIG. 1 is an exemplary circuit diagram illustrating a failure detecting circuit of an IGBT power module of the related art;

FIG. 2 is an exemplary circuit diagram illustrating a failure detecting circuit of an IGBT power module according to an exemplary embodiment of the present invention; and

FIG. 3 is an exemplary view illustrating a waveform when the failure is detected as a test result of a failure detecting circuit of an IGBT power module according to an exemplary embodiment of the present invention.

### DESCRIPTION OF SYMBOLS

Reference numerals set forth in the Drawings includes reference to the following elements as further discussed below:
10: IGBT power module
11: IGBT
12: gate drive IC
20: photo coupler
21: photo-diode
22: photo transistor
30: logic gate IC
31: two-channel AND gate
32: three-channel NAND gate
3: inverter gate
34: integrated signal line
6: digital power line
38: resistor
40: microcomputer

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter reference will now be made in detail to various embodiments of the present invention, examples of which are illustrated in the accompanying drawings and described below. While the invention will be described in conjunction with exemplary embodiments, it will be understood that present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

It is understood that the term “vehicle” or “vehicular” or other similar term as used herein is inclusive of motor vehicle in general such as passenger automobiles including sports utility vehicles (SUV), buses, trucks, various commercial vehicles, watercraft including a variety of boats, ships, aircraft, and the like and includes hybrid vehicles, electric vehicles, combustion, plug-in hybrid electric vehicles, hydrogen-powered vehicles and other alternative fuel vehicles (e.g. fuels derived from resources other than petroleum).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, in order to make the description of the present invention clear, unrelated parts are not shown and, the thicknesses of layers and regions are exaggerated for clarity. Further, when it is stated that a layer is “on” another layer or substrate, the layer may be directly on another layer or substrate or a third layer may be disposed therebetween.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor. The memory is configured to store the modules and the processor is specifically configured to execute said modules to perform one or more processes which are described further below.

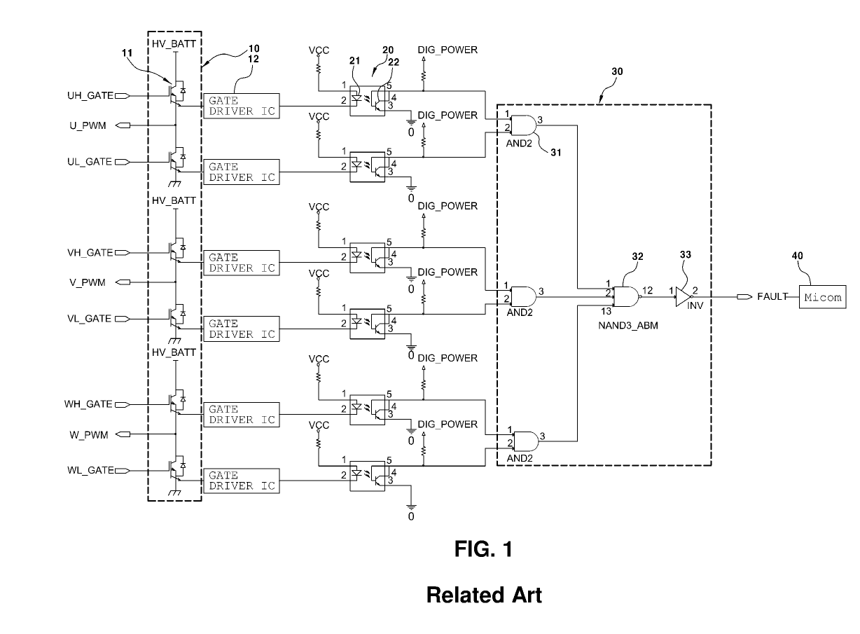

A failure detecting circuit of an IGBT power module of the related art will be described below. FIG. 1 illustrates an exemplary failure detecting circuit of an IGBT power module of the related art. In FIG. 1, reference numeral 10 denotes a gate drive integrated circuit (IC) which operates a gate of an IGBT. The gate drive IC 12 that operates an IGBT gate of the IGBT power module 10 is configured to be a circuit in a high voltage region together with the IGBT 11 to output failure detecting information. For example, overheating failure detecting information, arm-short or short circuit (hereinafter, referred to as arm-short) detecting information, overcurrent detecting information, or under voltage locked out (UVLO) detecting information of IGBT, as a digital signal (high or low) is provided.

In other words, the digital failure detecting signal detected by the gate drive IC 12 disposed in the high voltage region is transmitted to the microcomputer disposed in the low voltage region to operate the motor system. In particular, the digital failure detecting signal is detected by the gate drive IC 12 and is transmitted to the lower voltage region using an isolation type digital element such as a photo coupler 20. For example, a failure detecting signal such as overheating, arm-short, overcurrent, and UVLO detected by total six-phase IGBT gate drive IC 10 is a failure detecting signal for each phase IGBT. Further, each isolated failure detecting signal is transmitted to the low voltage region via a total of six photo couplers 20. In other words, a logic gate IC that includes three two-channel logic gate (AND) gates 31, one three-channel negative AND (NAND) gate 32, and one buffering inverter gate 33 is coupled to an output terminal of the photo coupler 20.

One of three two-channel AND gates is coupled to output terminals of two photo-couplers among total of six photo couplers 20, another of the three two-channel AND gates is coupled to output terminals of another two photo couplers of total of six photo couplers 20, and the other one of the three two-channel AND gates is connected to output terminals of the other two photo couplers of total of six photo couplers 20. Output terminals of two-channel AND gates 31 are simultaneously coupled to an input terminal of the three-channel NAND gate 32 and the buffering inverter gate 33 is coupled to an output terminal of the three-channel NAND gate 32.

When the total of six-phase IGBTs are in a normal state, a failure detecting signal output terminal of the gate drive IC 10 is maintained in an open position or a high impedance (Hi-Z) state. Since the photo coupler is not driven, the logic gate IC 30 detects a final fault which is a signal that indicates failure as a high value and transmits the final fault to the microcomputer 40.

In contrast, when at least one phase among total of six phases IGBTs shows a failure, the failure detecting signal output terminal that corresponds to the gate drive IC 10 is disposed in a low state and at least one of the six photo couplers is engaged, to transmit an isolated failure detecting signal which is shifted in a low state is transmitted to the logic gate IC 30. Therefore, the logic gate IC 30 includes the two-channel AND gate 31, the three-channel NAND gate 32, and the buffering inverter gate 33 detects the final fault FAULT as a low value and transmits the final fault to the microcomputer 40.

Furthermore, when the final fault FAULT signal is transmitted to the microcomputer 40, the microcomputer is configured to operate a motor system and output an appropriate command in consideration of safety of passengers of a vehicle. However, the six phase digital signal (e.g., the failure detecting signal) transmitted via the photo coupler is detected using a plurality of logic gates such as three two-channel AND gates, one three-channel NAND gate 32, and one buffering inverter gate 33. Accordingly, a material cost is increased, a size of the board is increased, and power consumption by the logic gate IC is also increased.

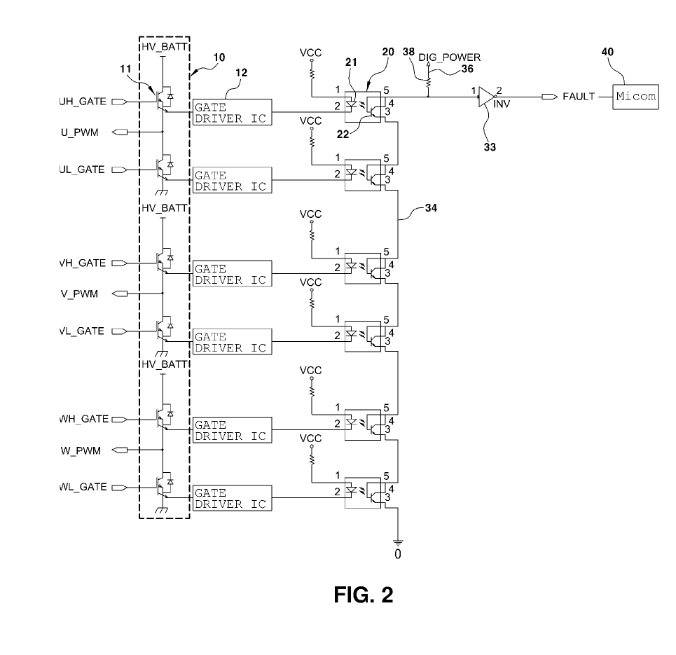

Hereinafter, an exemplary embodiment of the present invention will be described in detail with reference to the accompanying drawings. FIG. 2 illustrates an exemplary failure detecting circuit of an IGBT power module according to an exemplary embodiment of the present invention. As illustrated in FIG. 2, each of three phases (U phase, V phase, and W phase) may include a top phase and a bottom phase, and the IGBT power module 10 may include a total of six-phase (UT phase, UB phase, VT phase, VB phase, WT phase, and WB phase) IGBTs 11. Further isolation type photo couplers 20 may be coupled to each phase IGBT 11, and a failure detecting circuit that determines failure of the IGBT may be coupled to each photo coupler 20.

The gate drive integrated circuit (IC) 12 which drives an IGBT gate of the IGBT power module 10 may be a circuit in a high voltage region together with the IGBT 11 to output failure detecting information, such as overheating failure detecting information, arm-short detecting information, overcurrent detecting information, or UVLO detecting information of IGBT, as a digital signal (high or low). In other words, the digital failure detecting signal may be detected by the gate drive IC 12 that may be disposed in the high voltage region to be transmitted to the microcomputer disposed in the low voltage region configured toto operate the motor system. Further, the digital failure detecting signal detected by the gate drive IC 12 may be transmitted to the lower voltage region using an isolation type digital element such as a photo coupler 20. The photo coupler 20 may include by a photo-diode 21 coupled to a gate drive IC 12 disposed in the high voltage region and a photo-transistor 22 coupled to the low voltage region.

The present invention may include the photo-couplers 20 stacked or connected in series to detect a six-phase signal obtained by transmitting the isolated failure detecting signal such as overheating, arm-short, overcurrent, or UVLO detected by the IGBT gate drive IC 12, using the photo coupler 20 as a single integrated failure detecting signal. In particular, a photo coupler 20 may be coupled to each of a total of six gate drive ICs 12 that operate the total of six-phase IGBT gates. Further, output terminals of the photo couplers 20 may be connected in series by one integrated signal line 34. In particular, one end of the integrated signal line 34 may be grounded and one buffering inverter gate 33 may be connected to the other end of the integrated signal line 34. A digital power line 36 that supplies power may be connected to a part of the integrated signal line 34 that extends to the inverter gate 33 after connecting the photo couplers 20 may be coupled in series.

A resistor 38 may include a resistance set based on of a voltage level of the inverter gate 33 and may be connected to the digital power line 36. In other words, the resistor 38 may include a resistance set based on a of voltage levels high level input (V_IH) and low level input (V_IL) of the inverter gate 33 and may be connected to the digital power line 36. For example, V_IH of the inverter gate may indicate a threshold voltage indicating whether to output a digital signal FAULT that notifies the failure to be high when an input voltage VIN or lower is input to the inverter gate, and V_IL of the inverter gate indicates a threshold voltage indicating whether to output a digital signal FAULT that notifies the failure to be low when an input voltage VIN or higher is input to the inverter gate.

In other words, according to the voltage characteristic of the photo coupler 20, a voltage (V-CE) when the photo coupler is turned on may vary based on a current (I_F) value of the photo diode and a current (I_C) value of the phototransistor. Therefore, to satisfy conditions when the IGBT power module is in a normal state, FAULT may be configured to have a high output and when the IGBT power module is in a failure state, FAULT may be configured to have a low output, the conditions of the input voltage (VIN) of the inverter gate may be determined as described below.

### 1) Normal State Condition

When V_IH (threshold voltage)>VIN (inverter gate input voltage), VIN=6*V_CE. For example when, V_CE is a voltage when one photo coupler is turned on and 6*V_CE is a voltage when a total of six photo couplers are turned on. A current may flow into one photo coupler, in particular, a current (I_C) may flow into one phototransistor that may be represented by Equation 1.

I_C=(DIG_POWER-6*V_CE)/R Equation 1:

In Equation 1, I_C is a current which flows into one phototransistor, a voltage from a power supply connected to the digital power line, V_CE is a voltage when the photo coupler is engaged (V_CE), and R is a resistance (R) of the resistor 38 is connected to the digital power line 36.

### 2) Failure State Condition

When V_IL (threshold voltage)<VIN (inverter gate input voltage), VIN=DIG_POWER. In particular, to satisfy the conditions 1 and 2 described above, the photo couple may include V_CE or I_C and the resistance (R) of the resistor 38 may be selected. Further, a separate voltage dividing resistor may be connected to a inverter gate input voltage (VIN) node to achieve a circuit design that may satisfy the above conditions 1 and 2. In particular, an operation of the failure detecting circuit for an IGBT power module according to an exemplary embodiment of the present invention will be described below.

Normal State of IGBT Power Module

When the IGBT power module is in a normal state, a failure detecting signal output terminal of the gate drive IC 12 may be set to be maintained in a low state and the six photo couplers 20 may be engaged. For example, when a voltage (V_CE) of one photo coupler is engaged may be about 0.1 V, a voltage 6*V_CE when the total of six photo couplers are engaged may be about 0.6 V and the voltage 6*V_CE when the total of six photo couplers are engaged may become inverter gate input voltage (VIN)

For example, when a threshold voltage (V_IH) may be about 1.5 V, V_IH (threshold voltage=1.5 V)>VIN (inverter gate input voltage=0.6 V) may be satisfied and thus about 0.6 V of VIN may be input to the inverter gate 33 via the integrated signal line 34. Accordingly, the inverter gate 33 may be configured to output the digital signal FAULT that notifies the failure to be high, which indicates that the IGBT power module is in the normal state.

Failure State of IGBT Power Module

When at least one phase of the total of six-phase IGBTs which configure the IGBT power module is broken, the failure detecting signal output terminal of the corresponding gate drive IC 12 may be adjusted to an open state or a high impedance (Hi-Z) state therefore that at least one of the six photo couplers may be disengaged. Therefore, a voltage when the photo coupler is engaged the voltage may not be input to the inverter gate 33 and inverter gate input voltage (VIN) that may be input to the inverter gate 33 may include a voltage (DIG_POWER) from a power supply that may be connected to the digital power line 36. For example, when a threshold voltage (V_IL) may be about 1.5 V and a voltage DIG_POWER from the power supply coupled to the digital power line 36 may be about 3V, the V_IL (threshold voltage=1.5 V)<VIN (inverter gate input voltage=3V) may be satisfied and thus about 3V of inverter gate input voltage (VIN) may be input to the inverter gate 33 through the integrated signal line 34.

Accordingly, the inverter gate 33 may be configured to output the digital signal FAULT which may notify the failure to be low, which indicates that the IGBT power module operates in the failure state. Furthermore, the fault FAULT signal may be configured to be transmitted to the microcomputer 40 and the microcomputer 40 may be configured to operate a motor system and outputs an appropriate command in consideration of safety of passengers of a vehicle, based on the transmitted fault signal.

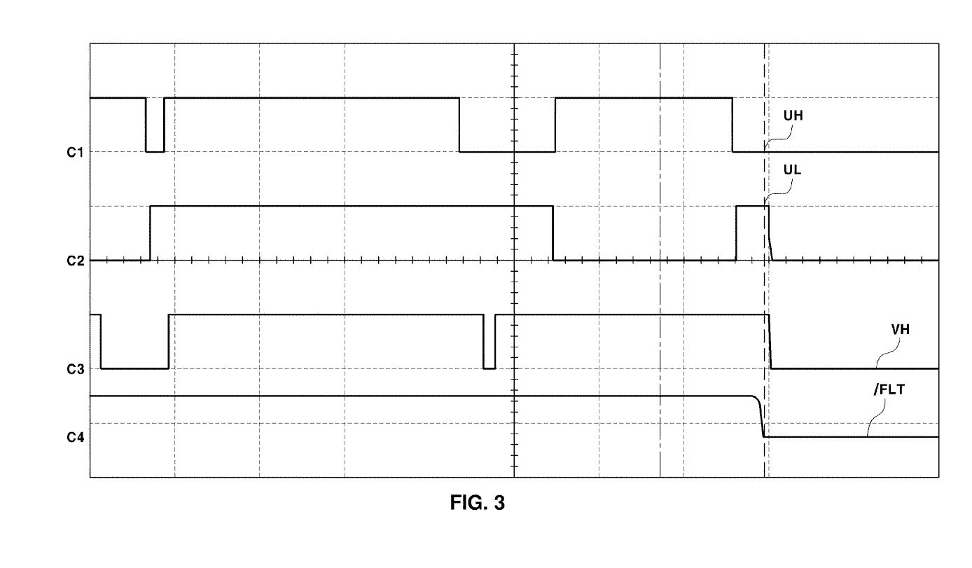

FIG. 3 is an exemplary view illustrating a waveform when the failure is detected as a test result of a failure detecting circuit of an IGBT power module according to an exemplary embodiment of the present invention. In FIG. 3, a first capacitor (C1) denotes a UH phase PWM signal, a second capacitor (C2) is a UL phase PWM signal, a third capacitor (C3) is a VH phase PWM signal, and a fourth capacitor (C4) is an integrated failure detecting signal (hereinafter, referred to as /FLT). Further, the failure of the IGBT power module may be detected and thus the /FLT signal may be adjusted from high (normal) to low (failure) and simultaneously, the PWM signals may be disengaged.

As described above, a plurality of photo coupler output terminals may be coupled in series by one integrated signal line to combine isolated six phase failure detecting signals that may be transmitted from the gate drive IC via the photo coupler into one voltage signal. Accordingly, reducing a material cost, a size of the board, and power consumption may be provided without the plurality of logic gate ICs of the related art.

The invention has been described in detail with reference to exemplary embodiments thereof. However, it will be appreciated by those skilled in the art that changes may be made in these exemplary embodiments without departing from the principles and spirit of the invention, the scope of which is defined in the appended claims and their equivalents.

What is claimed is:

1. A failure detecting circuit of an insulated-gate bipolar transistor (IGBT) power module, comprising:
a gate drive integrated circuit (IC) configured to operate a plurality of IGBT gate of an IGBT power module; and
a plurality of photo couplers configured to transmit an isolated digital failure detecting signal that is detected by the gate drive IC to a low voltage region,
wherein one integrated signal line is coupled to output terminals of the photo couplers to connect the photo couplers in series and a digital power line that supplies power is coupled to the integrated signal line to determine the failure of the IGBT power module based on a voltage signal that is transmitted from the integrated signal line and the digital power line.

2. The failure detecting circuit of claim 1, wherein one end of the integrated signal line is grounded and an inverter gate that outputs a signal indicating whether the IGBT power module is in a failure state is coupled to the other end of the integrated signal line.

3. The failure detecting circuit of claim 1, wherein a resistor having a resistance set based on voltage levels high level input (V_IH) and low level input (V_IL) of the inverter gate is coupled to the digital power line.

4. The failure detecting circuit of claim 1, wherein when the IGBT power module operates in a normal state, a failure detecting signal output terminal of the gate drive IC is maintained less than a predetermined level, and the the plurality of photo couplers are engaged.

5. The failure detecting circuit of claim 4, wherein when the plurality of photo couplers are engages, the inverter gate is configured to output a digital signal FAULT that indicates whether the inverter gate is in a failure state greater than a predetermined level, which indicates a normal operation.

6. The failure detecting circuit of claim 1, wherein when at least one phase IGBT of the plurality of IGBT power modules is in a failure state, a failure detecting signal output terminal of the gate drive IC is disposed in an open state or a high impedance (Hi-Z) state, and at least one of the plurality of photo couplers is disengaged.

7. The failure detecting circuit of claim 6, wherein when at least one of the plurality of photo couplers is disengaged, the inverter gate is configured to output a digital signal FAULT that indicates whether the inverter gate is in a failure state below a predetermined level, that indicates a failure state.

8. The failure detecting circuit of claim 5, wherein the fault signal is configured to be transmitted to a microcomputer and the microcomputer is configured to output an appropriate command to operate a motor system based on the fault signal.

9. The failure detecting circuit of claim 7, wherein the fault signal is configured to be transmitted to a microcomputer and the microcomputer is configured to operate an appropriate command to operate a motor system based on the fault signal.
